(19) United States
(12) Patent Application Publication
(10) Pub. No.: US 2003/0173662 A1
(43) Pub. Date: Sep. 18, 2003

(54) Electronic equipment having electronic part mounted on printed circuit board with under-fill material

(76) Inventor: Takumi Oikawa, Chita-gun (JP)

Correspondence Address: HARNESS, DICKEY & PIERCE, P.L.C., P.O. BOX 828, BLOOMFIELD HILLS, MI, 48303, US

(21) Appl. No.: 10/366,928

(22) Filed: Feb. 14, 2003

(30) Foreign Application Priority Data
Mar. 18, 2002 (JP) 2002-074460

(51) Int. Cl. H01L 23/12

(52) U.S. Cl. 257/711

(57) ABSTRACT

Electronic equipment is composed of a circuit board with a surface-printed circuit layer, an electronic part with a terminal, an under-fill provided between the electronic part and the surface-printed circuit layer. The terminal is electrically connected to the surface-printed circuit layer so that the electronic part is mounted on the circuit boarding an area, in which the circuit board faces the bottom face of the electronic part except for the terminal. The under-fill directly contacts the electronic part and the surface-printed circuit layer so that the under-fill fixes the electronic part to the circuit board.

### CROSS REFERENCE TO RELATED APPLICATION

This application relates to and incorporates herein by reference Japanese Patent Application No. 2002-74460 filed on Mar. 18, 2002.

### FIELD OF THE INVENTION

The present invention relates to electronic equipment that has an electronic part mounted on a printed circuit board with under-fill material, and a method of manufacturing the electronic equipment.

### BACKGROUND OF THE INVENTION

Electronic equipment is generally composed of an electronic part and a circuit board shown in FIGS. 4 and 5. In this equipment, the electronic part has an integrated circuit package (i.e., IC package), which is, for example, a surface mount type thin small out-line package 10 (i.e., a surface mount type TSOP 10, which is abbreviated as TSOP 10 as follows). The circuit board is used as a multi-layer printed circuit board 3. The multi-layer printed circuit board 3 is a circuit board, in which an insulating layer and a printed circuit layer are stacked alternately.

The TSOP 10 involves a package 1 and a lead 2 for a terminal. An integrated circuit chip (i.e., IC chip, not shown in FIGS. 4 and 5) is sealed into the package 1. The lead 2 and the IC chip are connected electrically inside the package 1. A portion of the lead 2, which is located outside the package 1, is bent so as to be parallel to the surface of the circuit board 3. A bent portion of the lead 2 composes a contact area 2a, which connects to a surface-printed circuit layer on the circuit board 3.

A copper foil 4 as the surface-printed circuit layer is formed on the surface of the circuit board 3, which faces the TSOP 10. The surface-printed circuit layer is a most top layer of the circuit board 3 and is electrically connected to an electronic part with solder and so on. The copper foil 4 and the lead 2 are soldered together. Then, the TSOP 10 is electrically connected and fixed to the circuit board 3. A soldering area S for soldering the contact area 2a and the copper foil 4 is disposed on the surface of the circuit board 3 and faces the contact area 2a of the lead 2.

A photo-resist layer is formed on the copper foil 4 so that the photo-resist prevents solder 6 from adhering to the unnecessary surface of the circuit board 3, which is located on the other area of the soldering area S.

The copper foil 4a is also formed on the surface of the circuit board 3 in an area, in which the circuit board 3 faces the bottom face 1a of the package 1, due to ground electric potential or electric continuity between devices. The photo-resist layer 5a is also formed on the copper foil 4a in the above area so that the photo-resist layer 5a protects the copper foil 4a.

An under-fill 7 is made of under-fill material and formed under and around the bottom face 1a of the package 1. The TSOP 10 is also fixed to the surface of the circuit board 3 by the under-fill 7. When a mechanical stress or a thermal stress is applied to the circuit board 3, the solder 6 in the soldering area S cracks without the under-fill material 7. Therefore both the under-fill 7 and the solder 6 fix the TSOP 10 and the circuit board 3, and fixation strength of the TSOP 10 and the circuit board 3 is secured.

In another electronic equipment shown in FIG. 5, an electronic part 20 may be replaced with the TSOP 10 shown in FIG. 4. A terminal 12 of the electronic part 20 is disposed at a predetermined position of a bottom face 11a of a package 11. The electronic part 20 accommodates an IC chip and a ceramic circuit board (not shown in FIG. 5). The IC chip is mounted and electrically connected to the ceramic circuit board. The terminal 12 is formed outside the package 11 so that a contact area 12a of the terminal 12 and the bottom face 11a of the package 11 are on the same plane. The terminal 12 is fixed and electrically connected to the ceramic circuit board inside the package 11.

In this case, similar to the electronic part 10 shown in FIG. 4, the terminal 12 of the electronic part 20 and the copper foil 4 are soldered so that the electronic part 20 and a multi-layer printed circuit board 3 are fixed and electrically connected. A photo-resist layer 5, 5a is formed on the surface of the circuit board 3 in an area, which is located on the other area of the soldering area S. Therefore, the photo-resist layer 5a is formed on the copper foil 4a in area A, in which the circuit board 3 faces the electronic part 20 except for the contact area 12a of the terminal 12.

As shown in FIGS. 4 and 5, the copper foil 4a is formed on the circuit board 3 even in the area, in which the electronic part is mounted. Further, the copper foil 4a in this area is covered with the photo-resist layer 5a, because this area is unnecessary soldering area.

As shown in FIG. 4, spacing between the bottom face 1a of the TSOP 10 and the photo-resist layer 5a on the circuit board 3 is excessively small so that it is difficult to impregnate an under-fill material into the spacing. As shown in FIG. 5, it is preferred that the electronic part 20 is also fixed to the circuit board 3 with the under-fill for reinforcing the fixation by the solder 6. But the under-fill material cannot be impregnated between the electronic part 11 and the circuit board 3, because the spacing between the electronic part 11 and the photo-resist layer 5a on the circuit board 3 is substantially zero.

Therefore, the under-fill does not sufficiently fix the electronic part to the circuit board, and does not sufficiently reinforce the solder fixation between the electronic part and the circuit board. This problem emerges in electronic equipment that has small difference between a height of a bottom face of an electronic part from a surface of a circuit board and a height of a contact area of a terminal from the surface of the circuit board, when the electronic part is mounted on the circuit board.

### SUMMARY OF THE INVENTION

The present invention has an object to provide electronic equipment that has sufficiently wide spacing between an electronic part and a circuit board so that an under-fill material is impregnated into the spacing sufficiently. Moreover, the present invention has another object to provide a method of manufacturing the above electronic equipment.

Electronic equipment in the present invention comprises a circuit board with a surface-printed circuit layer, an electronic part with a terminal, a photo-resist layer, and an under-fill.

The terminal is electrically connected to the surface-printed circuit layer so that the electronic part is mounted on the circuit board. The surface-printed circuit layer is formed on the circuit board in an area, in which the circuit board faces the bottom face of the electronic part except for the terminal. The under-fill directly contacts the electronic part and the surface-printed circuit layer so that the under-fill fixes the electronic part to the circuit board.

The photo-resist layer is replaced with the surface-printed circuit layer, and is formed on the circuit board in an area, in which the circuit board faces the electronic part except for the terminal. Then, the under-fill directly contacts the electronic part and the photo-resist layer so that the under-fill fixes the electronic part to the circuit board.

Moreover, the surface-printed circuit layer is formed on the circuit board so that the surface of the circuit board in an area, in which the circuit board faces the electronic part except for the terminal, is exposed from the surface-printed circuit layer. Then, the under-fill directly contacts the electronic part and the circuit board so that the under-fill fixes the electronic part to the circuit board.

It is preferred that the spacing between the electronic part and the circuit board in a vertical direction of the circuit board, is 30 microns or over.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross-sectional view showing electronic equipment according to the first embodiment of the present invention;

FIG. 2 is a schematic cross-sectional view showing electronic equipment according to the second embodiment of the present invention;

FIG. 3 is a schematic cross-sectional view showing electronic equipment according to the third embodiment of the present invention;

FIG. 4 is a schematic cross-sectional view showing electronic equipment according to a related art;

FIG. 5 is a schematic cross-sectional view showing electronic equipment according to a related art.

### DETAILED DESCRIPTION OF THE PREFERRED EMBODIMENT

(First Embodiment)

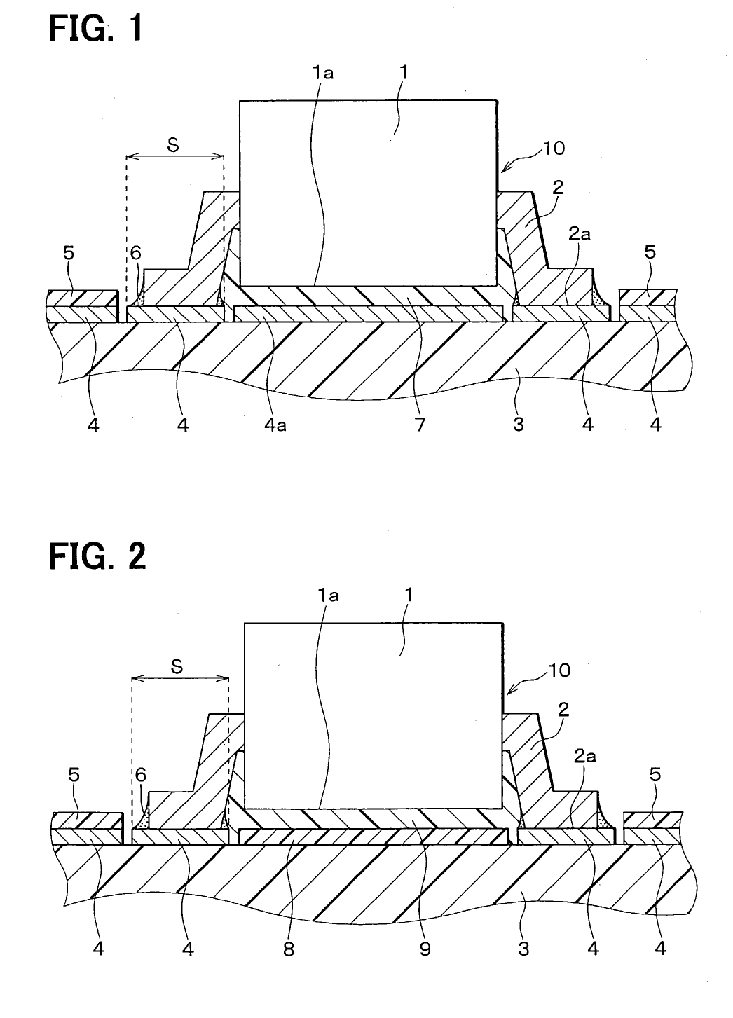

As shown in FIG. 1, electronic equipment according to the first embodiment is composed of an electronic part 10 and a circuit board 3. The electronic part 10 has an integrated circuit package (i.e., IC package), which is, for example, a surface mount type thin small out-line package 10 (i.e., a surface mount type TSOP 10, which is abbreviated as TSOP 10 as follows). The circuit board 3 is used as a multi-layer printed circuit board 3, which is made of glass-epoxy resin.

The TSOP 10 involves a package 1 and a lead 2 for a terminal. The lead 2, for example, is made of an iron-nickel alloy, of which a weight percentage is iron 58 wt. % to nickel 42 wt. %. The entire bottom face 1a of the package 1 faces the circuit board 3.

A copper foil 4 as a surface-printed circuit layer is formed on a surface of the circuit board 3, which faces the TSOP 10. Especially, the copper foil 4 is formed on the surface in both areas, in which the circuit board 3 faces the bottom face 1a of the package 1, and in which the circuit board 3 faces the contact area 2a of the lead 2. A photo-resist layer 5 is formed on the copper foil 4 except a soldering area S, which is disposed on the surface of the multi-layer printed circuit board 3 and faces the contact area 2a of the lead 2. The photo-resist layer 5 is made of liquid type photo-resist for photography development, and prevents solder 6 from adhering to the unnecessary surface of the circuit board 3, which is located on the other area of the soldering area S.

The copper foil 4a is exposed from the resist layer 5 not only at the soldering area S but also at the area, in which the circuit board 3 faces the bottom surface 1a of the package 1. The copper foil 4 in the soldering area S and the contact area 2a of the lead 2 are soldered together. Then, the TSOP 10 is electrically connected and fixed to the circuit board 3.

As shown in FIG. 1, an under-fill 7 is provided between the bottom face 1a of the package 1 and the copper foil 4a. The under-fill 7 is also provided under the lead 2 so as to be protruded out of the spacing between the package 1 and the copper foil 4a. The under-fill 7 is made of thermosetting resin such as epoxy resin, which has excellent insulating property and low setting temperature lower than ambient temperature, at which the electronic part is placed.

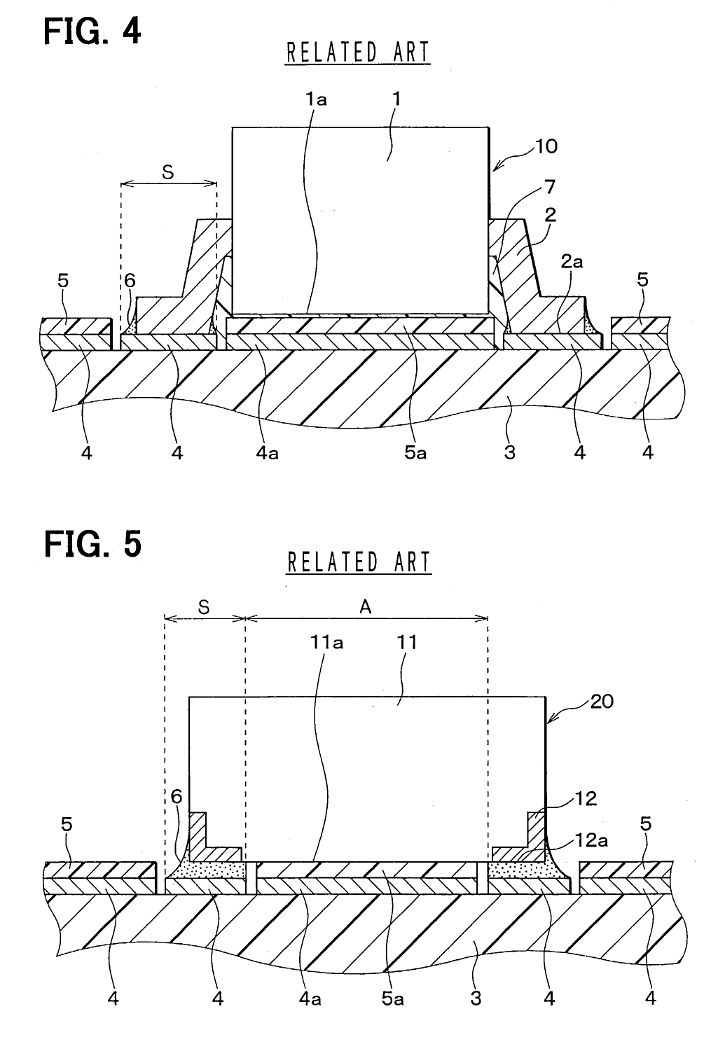

No photo-resist layer is provided on the copper foil 4a, which faces the bottom face 1a of the package 1, in comparison with the photo-resist layer 5a on the copper foil 4a according to the related art as shown in FIG. 4. Therefore, the under-fill 7 is formed directly on the above copper foil 4a. In other words, both the bottom face 1a of the package 1 and the copper foil 4a directly contact the under-fill 7. So the spacing between the circuit board 3 and the package 1 is enlarged more than that of the related art, in which the photo-resist layer 5a is formed on the copper foil 4a as shown in FIG. 4.

It is preferred that the spacing between the package 1 and the circuit board 3 is more than 30 microns. In this case, the under-fill material is impregnated into the spacing between the package 1 and the printed circuit board 3 sufficiently. In the first embodiment, the thickness of the photo-resist layer 5 is 38 microns, and the thickness of the copper foil 4 is 32 microns. When the TSOP 10 is mounted on the circuit board 3, the difference between the height of the bottom face 1a of the package 1 from the surface of the circuit board 3 and the height of the contact area 2a of the lead 2 from the surface of the circuit board 3 is 50 microns.

In the relate art, even the above difference is 50 microns, the spacing between the package 1 and the circuit board 3 is 12 microns because the spacing is narrowed by the thickness of the photo-resist layer 5a. Therefore, the under-fill material is not sufficiently impregnated into the spacing, and this causes a portion of the bottom face 1a, in which the under-fill 7 is not provided. However, in the first embodiment, no photo-resist layer 5a under the package 1 is provided, and the spacing between the package 1 and the copper foil 4a is 50 microns. Then, the spacing between the in the package 1 and the copper foil 4a is sufficiently secured.

The above electronic equipment is manufactured as follows.

At first, the multi-layer printed circuit board 3 is prepared, which has the above spacing. Concretely, the photo-resist layer 5 and the copper foil 4, which is covered with the photo-resist layer 5, are formed on the circuit board 3. No photo-resist layer is provided in the soldering area S and in the area, in which the circuit board 3 faces the bottom face 1a of the TSOP 10, so that the copper foils 4, 4a in those areas are exposed.

Then, the contact area 2a of the lead 2 and the copper foil 4 are soldered with solder 6, and the TSOP 10 is mounted and fixed on the circuit board 3. Moreover, the liquid type under-fill material is poured into the spacing between the bottom face 1a of the TSOP 10 and the copper foil 4a on the circuit board 3. Then, the under-fill material is solidified, and the under-fill 7 is formed. As a result, both the bottom face 1a of the TSOP 10 and the copper foil 4a directly contact the under-fill 7.

The under-fill 7 is poured in the following manner. If the under-fill 7 is poured into the spacing between the bottom face 1a of the package 1 and the copper foil 4a from all directions simultaneously, which surround the circumference of the TSOP 10, air is trapped in the under-fill material, which is poured into the spacing. Then, a void of the trapped air is formed when the under-fill material is solidified, and the fixation strength of the TSOP 10 and the circuit board 3 is not secured enough. To avoid this air trapping, the under-fill material is poured into the spacing from some directions, which surround the circumference of the TSOP 10, so that a portion of the circumference of the TSOP 10 is opened outside. Then, the air in the spacing is pushed out from the portion as the under-fill material is poured into the spacing. Therefore, the air is not trapped in the under-fill 7.

Besides, after the under-fill 7 is formed, the electronic part and the like are covered with dampproof material and so on. Then, the electronic equipment is tested in the testing process.

(Second Embodiment)

The TSOP 10 is mounted on the multi-layer printed circuit board 3, similar to the first embodiment. However, a photo-resist layer 8 is formed on the multi-layer printed circuit board 3 in an area, in which the circuit board 3 faces the bottom face 1a of the package 1, compared with the copper foil 4a in the first embodiment shown in FIG. 1. An under-fill 9 is provided directly on the photo-resist layer 8, and the under-fill 9 fixes the package 1 to the circuit board 3.

Then, no copper foil 4a is provided in the area, in which the circuit board 3 faces the bottom face 1a of the package 1, compared with electronic equipment according to the related art shown in FIG. 4.

Similar to the first embodiment, the thickness of the photo-resist layer 5 is 38 microns, and the thickness of the copper foil 4 is 32 microns. When the TSOP 10 is mounted on the circuit board 3, the difference between the height of the bottom face 1a of the package 1 from the surface of the circuit board 3 and the height of the contact area 2a of the lead 2 from the surface of the circuit board 3 is 50 microns. The spacing between the bottom face 1a of the package 1 and the photo-resist layer 8 is 44 microns. In this case, the under-fill material is impregnated into the spacing between the package 1 and the circuit board 3 sufficiently.

In comparison with the first embodiment, the photo-resist layer 5 and the copper foil 4 is slightly changed. The photo-resist layer 5 and the copper foil 4, which is covered with the photo-resist layer 5, are formed on the circuit board 3. No copper foil 4 is provided in the area, in which the circuit board 3 faces the bottom face 1a of the package 1. No photo-resist layer is provided in the soldering area S so that the copper foil 4a in this soldering area S is exposed, and the photo-resist layer 8 is provided in the area, in which the circuit board 3 faces the bottom face 1a of the package 1.

Then, the contact area 2a of the lead 2 and the copper foil 4 are soldered with solder 6, and the TSOP 10 is mounted and fixed on the circuit board 3. Moreover, the liquid type under-fill material is poured into the spacing between the bottom face 1a of the package 1 and the photo-resist layer 8 on the circuit board 3. Then, the under-fill material is solidified, and the under-fill 9 is formed. As a result, both the bottom face 1a of the package 1 and the photo-resist layer 8 directly contact the under-fill 9.

Therefore, the spacing between the package 1 and the circuit board 3 is secured enough so that the under-fill material is impregnated into the spacing between the package 1 and the circuit board 3 sufficiently. Then, the under-fill 9 reinforces the solder fixation of the TSOP 10 to the circuit board 3.

(Third Embodiment)

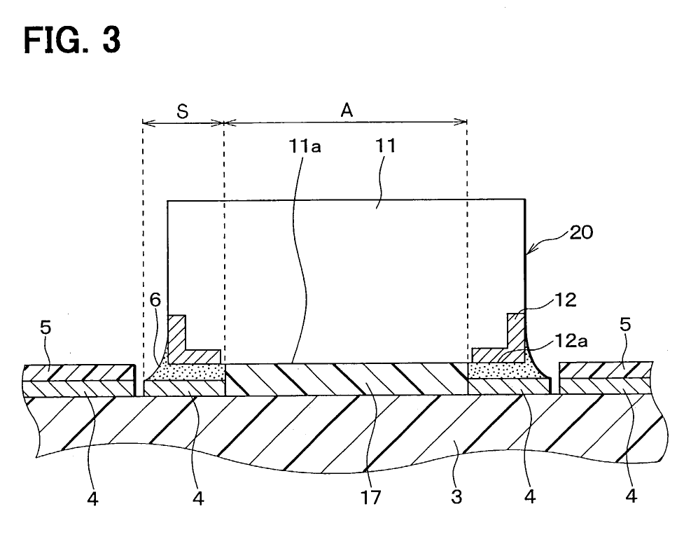

As shown in FIG. 3, the multi-layer printed circuit board 3 is used as a circuit board, similar to the first embodiment. However, an electronic part 20 in electronic equipment is substituted for the TSOP 10 in the first and second embodiments shown in FIGS. 1 and 2. A terminal 12 of the electronic part 20 is disposed at a predetermined position of a bottom face 11a of a package 11. The terminal 12 is formed outer side of the package 11 and also formed on both ends of the bottom face 11a of the package 11 so that a contact area 12a of the terminal 12 and the bottom face 11a of the package 11 are on the same plane.

Similar to the first embodiment, the photo-resist layer 5 and the copper foil 4, which is covered with the photo-resist layer 5, are formed on the circuit board 3. However, the copper foil 4 is not formed in area A, in which the circuit board 3 faces the bottom face 11a of the package 11 except for the contact area 12a of the terminal 12. Besides, the photo-resist layer 5 is not formed either in the area A. A solder 6 in the soldering area S is provided between the terminal 12 of the electronic part 20 and the copper foil 4 on the circuit board 3. This solder 6 electrically connects and fixes the electronic part 20 to the circuit board 3. An under-fill 17 is provided in the spacing between the circuit board 3 and the package 11 in the area A. The under-fill 17 also fixes the electronic part 20 to the circuit board 3.

In the first and second embodiments, the height of the bottom face 1a of the package 1 from the surface of the circuit board 3 is larger than the height of the contact area 2a of the lead 2 from the surface of the circuit board 3. Therefore, the spacing exists between the package 1 and the circuit board 3. Then, the electronic equipments in the first and second embodiments are formed to eliminate the photo-resist layer or the copper foil under the bottom face 1a of the package 1 from the electronic equipment according to the related art shown in FIG. 4. The under-fill material is impregnated sufficiently into the spacing between the electronic part 10 and the circuit board 3.

However, in the third embodiment, the contact area 12a of the terminal 12 and the bottom face 11a of the package 11 are on the same plane. Therefore, even when the electronic equipment in the third embodiment is formed to eliminate the photo-resist layer or the copper foil under the bottom face 11a of the package 11, the spacing between the package 1 and the circuit board 3 is not large enough.

Therefore, the electronic equipment is formed to eliminate both the photo-resist layer 5 and the copper foil 4 in the area A from the electronic equipment according to the related art shown in FIG. 5. For example, when the thickness of the copper foil 4 is 32 microns, the spacing between the package 11 and the multi-layer printed circuit board 3 is given by the addition of the thickness of the copper foil 4 and the thickness of the solder 6. Therefore, the spacing is larger than 30 microns.

The electronic equipment is manufactured as follows.

At first, the photo-resist layer 5 and the copper foil 4, which is covered with the photo-resist layer 5, are formed on the multi-layer printed circuit board 3. No copper foil 4 is provided in the area A, in which the circuit board 3 faces the package 11 except for the contact area 12a of the terminal 12. No photo-resist layer is provided in the soldering area S so that the copper foil 4 in the soldering area S is exposed. In this way, the copper foil 4 in the soldering area S is exposed from the photo-resist layer 5, and the surface of the circuit board 3 in the area A is exposed from both the copper foil 4 and the photo-resist layer 5.

Then, the contact area 12a of the terminal 12 and the copper foil 4 in the soldering area S are soldered with the solder 6, and the electronic part 20 is mounted and fixed to the circuit board 3. Moreover, the liquid type under-fill material is poured into the spacing between the bottom face 11a of the package 11 and the circuit board 3. The under-fill material is solidified and an under-fill 17 is formed. As a result, both the bottom face 11a of the package 11 and the circuit board 3 directly contact the under-fill 17.

In this case, the spacing between the electronic part 20 and the circuit board 3 is more than 30 microns, and the under-fill material is poured sufficiently into the spacing. Therefore, the under-fill 17 reinforces the solder fixation of the electronic part 20 to the circuit board 3.

When only the solder 6 fixes the electronic part 20 to the circuit board 3, the solder 6 cracks by temperature changes because the thermal coefficient of the circuit board 3 is different from that of the ceramic circuit board inside the electronic part 20. However, the under-fill 17 also fixes the electronic part 20 to the circuit board 3 strongly, and the fixation strength of the electronic part 20 to the circuit board 3 is higher than that in the case that only the solder 6 fixes the electronic part 20 to the circuit board 3.

(Modifications)

Although the present invention has been fully described in connection with the preferred embodiments thereof with reference to the accompanying drawings, it is to be noted that various changes and modifications will become apparent to those skilled in the art.

In the first and second embodiment, the TSOP 10 is used as the electronic part 10, for example. However, other surface mount type IC packages may be used as the electronic part, in which spacing between a bottom face of an electronic part and a surface-printed circuit layer on a circuit board is more than 30 microns when the electronic part is mounted on the circuit board. Moreover, other electronic parts may be used as the electronic part in addition to IC device.

Further, in the third embodiment, the terminal 12 is formed on the bottom face 11a of the electronic part 11, for example. However, other electronic part may be used as the electronic part 20, in which a contact area of a terminal is apart from a bottom face of an electronic part when the electronic part is mounted on a circuit board. For example, the TSOP, which is used as the electronic part 10 in the first and second embodiments, may be also used as the electronic part 20 in the third embodiment. In this case, the spacing between the TSOP and the circuit board is larger than that in the first and second embodiments. Furthermore, in the third embodiment, other surface mount type IC packages may be used as the electronic part, in which spacing between a bottom face of an electronic part and a surface-printed circuit layer is more than 30 microns when the electronic part is mounted on a circuit board. Moreover, other electronic parts may be also used as the electronic part in addition to IC device.

Furthermore, the electronic part 10, 20 has the package 1, 11, for example. However, an electronic part, which does not have a package, may be used as the electronic part. Although the surface-printed circuit layer is composed of copper foil, the surface-printed circuit layer may be composed of copper layer with gold plating or the like. Also other conductive materials may be used as the surface-printed circuit layer. Although the multi-layer printed circuit board 3 is made of glass-epoxy resin, other multi-layer printed circuit boards, which are made of paper, phenol resin, or ceramic, may be used as the multi-layer printed circuit board. Besides, other circuit boards may be used in place of the multi-layer printed circuit board, for example, single layer printed circuit board and double layer printed circuit board.

Such changes and modifications are to be understood as being within the scope of the present invention as defined by the appended claims.

What is claimed is:

1. Electronic equipment comprising:
a circuit board with a surface-printed circuit layer;
an electronic part with a terminal; and
an under-fill provided between the electronic part and the surface-printed circuit layer,
wherein the terminal is electrically connected to the surface-printed circuit layer so that the electronic part is mounted on the circuit board,
wherein the surface-printed circuit layer is provided on the circuit board in an area, in which the circuit board faces a bottom face of the electronic part except for the terminal, and
wherein the under-fill directly contacts the electronic part and the surface-printed circuit layer so that the under-fill fixes the electronic part to the circuit board.

2. Electronic equipment according to claim 1, wherein spacing between the electronic part and the surface-printed circuit layer in a vertical direction of the circuit board, is 30 microns or over.

3. Electronic equipment according to claim 1, further comprising:
a solder, with which the terminal is electrically connected and fixed to the surface-printed circuit layer,
wherein the under-fill reinforces the solder fixation between the electronic part and the circuit board.

4. Electronic equipment according to claim 3, wherein the spacing between the electronic part and the circuit board is provided by the addition of the thickness of the solder.

5. Electronic equipment comprising:
a circuit board with a surface-printed circuit layer;
an electronic part with a terminal;
a photo-resist layer; and
an under-fill provided between the electronic part and the photo-resist layer,
wherein the terminal is electrically connected to the surface-printed circuit layer so that the electronic part is mounted on the circuit board,
wherein the photo-resist layer is provided on the circuit board in an area, in which the circuit board faces a bottom face of the electronic part except for the terminal, and
wherein the under-fill directly contacts the electronic part and the photo-resist layer so that the under-fill fixes the electronic part to the circuit board.

6. Electronic equipment comprising:
a circuit board with a surface-printed circuit layer;
an electronic part with a terminal; and
an under-fill provided between the electronic part and the circuit board,
wherein the terminal is electrically connected to the surface-printed circuit layer so that the electronic part is mounted on the circuit board,
wherein the surface-printed circuit layer is provide on the circuit board so that the surface of the circuit board is exposed from the surface-printed circuit layer in an area, in which the circuit board faces a bottom face of the electronic part except for the terminal, and
wherein the under-fill material directly contacts the electronic part and the circuit board so that the under-fill material fixes the electronic part to the circuit board.

7. Electronic equipment according to claim 6, further comprising:
a solder, with which the terminal is electrically connected and fixed to the surface-printed circuit layer,
wherein the under-fill reinforces the solder fixation between the electronic part and the circuit board, and
wherein the spacing between the electronic part and the circuit board is provided by the addition of the thickness of the solder.

8. A method of manufacturing electronic equipment, which is composed of a circuit board with a surface-printed circuit layer, an electronic part with a terminal, and an under-fill, comprising:
forming the surface-printed circuit layer on the circuit board in an area, in which the circuit board faces the electronic part except for the terminal;
fixing and electrically connecting the terminal of the electronic part to the surface-printed circuit layer so that the electronic part is mounted on the circuit board; and
providing the under-fill, which directly contacts the electronic part and the surface-printed circuit layer so that the under-fill fixes the electronic part to the circuit board.

9. A method of manufacturing electronic equipment according to claim 8, wherein the under-fill is made of a liquid-type under-fill material and the liquid-type under-fill material is poured into the spacing between the electronic part and the copper foil in only certain directions, which surround the circumference of the electronic part, so that a portion of the circumference of the electronic part is opened outside.

10. A method of manufacturing electronic equipment, which is composed of an circuit board with a surface-printed circuit layer, an electronic part with a terminal, a photo-resist layer, and an under-fill, comprising:
forming the photo-resist layer on the circuit board in an area, in which the circuit board faces the electronic part except for the terminal;
fixing and electrically connecting the terminal of the electronic part to the surface-printed circuit layer so that the electronic part is mounted on the circuit board; and
providing the under-fill, which directly contacts the electronic part and the photo-resist layer, so that the under-fill fixes the electronic part to the circuit board.

11. A method of manufacturing electronic equipment, which is composed of an circuit board with a surface-printed circuit layer, an electronic part with a terminal, and an under-fill, comprising:
forming the surface-printed circuit layer on the circuit board so that the surface of the circuit board is exposed from the surface-printed circuit layer in an area, in which the circuit board faces the electronic part except for the terminal;
fixing and electrically connecting the terminal of the electronic part to the surface-printed circuit layer so that the electronic part is mounted on the circuit board; and
providing the under-fill, which directly contacts the electronic part and the circuit board, so that the under-fill fixes the electronic part to the circuit board.
